(19) United States
(12) Patent Application Publication
(10) Pub. No.: US 2026/0081563 A1
(43) Pub. Date: Mar. 19, 2026

(54) DOHERTY POWER AMPLIFIERS WITH INDUCTOR-CAPACITOR LATTICE FOR IMPEDANCE INVERSION

(71) Applicant: Skyworks Solutions, Inc., Irvine, CA (US)

(72) Inventors: Seunghwan Yoon, Irvine, CA (US); Hyeong Tae Jeong, Westlake Village, CA (US); Bo Pan, Irvine, CA (US)

(21) Appl. No.: 19/328,759

(22) Filed: Sep. 15, 2025

Related U.S. Application Data
(60) Provisional application No. 63/696,272, filed on Sep. 18, 2024.
(60) Provisional application No. 63/696,267, filed on Sep. 18, 2024.

(51) Int. Cl. H03F 1/02; H03F 3/24

(52) U.S. Cl. CPC H03F 1/0288; H03F 3/245; H03F 2200/451

(57) ABSTRACT

Doherty power amplifiers with an inductor-capacitor (LC) lattice for impedance inversion are disclosed. In certain embodiments, a Doherty power amplifier includes a carrier amplifier, a peaking amplifier, and an LC lattice that serves as an impedance inverter for combining a differential carrier signal from the carrier amplifier with a differential peaking signal from the peaking amplifier. The LC lattice can include series inductors and cross capacitors connected to form a lattice, or series capacitors and cross inductors connected to form the lattice.

### CROSS-REFERENCE TO RELATED APPLICATIONS

This application claims the benefit of priority under 35 U.S.C. § 119 of U.S. Provisional Patent Application No. 63/696,272, filed Sep. 18, 2024 and titled “DOHERTY POWER AMPLIFIERS WITH INDUCTOR-CAPACITOR LATTICE FOR IMPEDANCE INVERSION,” and of U.S. Provisional Patent Application No. 63/696,267, filed Sep. 18, 2024 and titled “INDUCTOR-CAPACITOR LATTICE FOR DOHERTY POWER AMPLIFIERS,” each of which is herein incorporated by reference in its entirety.

### BACKGROUND

### Technical Field

Embodiments of the invention relate to electronic systems, and in particular, to radio frequency (RF) electronics.

### Description of Related Technology

Power amplifiers are used in RF communication systems to amplify RF signals for transmission via antennas.

Examples of RF communication systems with one or more power amplifiers include, but are not limited to, mobile phones, tablets, base stations, network access points, customer-premises equipment (CPE), laptops, and wearable electronics. For example, in wireless devices that communicate using a cellular standard, a wireless local area network (WLAN) standard, and/or any other suitable communication standard, a power amplifier can be used for RF signal amplification. An RF signal can have a frequency in the range of about 30 kHz to 300 GHz, such as in the range of about 400 MHz to about 7.125 GHz for Frequency Range 1 (FR1) of the Fifth Generation (5G) communication standard or in the range of about 24.250 GHz to about 71.000 GHz for Frequency Range 2 (FR2) of the 5G communication standard.

### SUMMARY

In certain embodiments, the present disclosure relates to a mobile device. The mobile device includes a transceiver configured to generate a radio frequency input signal and a front-end system including a Doherty power amplifier configured to amplify the radio frequency input signal. The Doherty power amplifier includes a carrier amplifier having a non-inverted carrier output and an inverted carrier output, a peaking amplifier having a non-inverted peaking output and an inverted peaking output, and an impedance inverter including a first series inductor having a first end electrically connected to the inverted carrier output and a second end electrically connected to the inverted peaking output, a second series inductor having a first end electrically connected to the non-inverted carrier output and a second end electrically connected to the non-inverted peaking output, a first cross capacitor electrically connected between the first end of the first series inductor and the second end of the second series inductor, and a second cross capacitor electrically connected between the first end of the second series inductor and the second end of the first series inductor.

In some embodiments, the first series inductor is electromagnetically coupled to the second series inductor to provide a mutual inductance.

In various embodiments, the Doherty power amplifier further includes an output balun having a primary winding electrically connected between the non-inverted peaking output and the inverted peaking output. According to a number of embodiments, a secondary winding of the output balun is electrically connected between a radio frequency output terminal and a ground voltage, the radio frequency output terminal providing a radio frequency output signal that is amplified relative to the radio frequency input signal. In accordance with several embodiments, the mobile device further includes an antenna configured to transmit the radio frequency output signal.

In some embodiments, the impedance inverter includes two or more stages, a first stage of the two or more stages including the first series inductor, the second series inductor, the first cross capacitor, and the second cross capacitor. According to a number of embodiments, a second stage of the two or more stages includes a third series inductor having a first end electrically connected to the second end of the first series inductor and a second end electrically connected to the inverted peaking output, a fourth series inductor having a first end electrically connected to the second end of the second series inductor and a second end electrically connected to the non-inverted peaking output, a third cross capacitor electrically connected between the first end of the third series inductor and the second end of the fourth series inductor, and a fourth cross capacitor electrically connected between the first end of the fourth series inductor and the second end of the third series inductor.

In various embodiments, the front-end system includes a radio frequency module including a module substrate and a semiconductor die attached to the module substrate, the carrier amplifier and the peaking amplifier formed on the semiconductor die. According to a number of embodiments, the first cross capacitor and the second cross capacitor are formed on the semiconductor die, and the first series inductor and the second series inductor are formed as surface mount components attached to the module substrate.

In several embodiments, the carrier amplifier receives the radio frequency input signal, the Doherty power amplifier further including an input phase shifter configured to receive the radio frequency input signal and to provide a delay radio frequency input signal to the peaking amplifier, the radio frequency input signal and the delayed radio frequency input signal having a phase shift of about ninety degrees.

In some embodiments, the carrier amplifier further includes a first carrier bipolar transistor having a collector electrically connected to the non-inverted carrier output and a second carrier bipolar transistor having a collector electrically connected to the inverted carrier output, the peaking amplifier including a first peaking bipolar transistor having a collector electrically connected to the non-inverted peaking output and a second peaking bipolar transistor having a collector electrically connected to the inverted peaking output. According to a number of embodiments, the carrier amplifier includes a carrier balun having a secondary winding electrically connected between a base of the first carrier bipolar transistor and a base of the second carrier bipolar transistor, the peaking amplifier further including a peaking balun having a secondary winding electrically connected between a base of the first peaking bipolar transistor and a base of the second peaking bipolar transistor.

In various embodiments, the Doherty power amplifier provides amplification for two or more frequency bands. In accordance with a number of embodiments, the two or more frequency bands include n255 and n256.

In certain embodiments, the present disclosure relates to a Doherty power amplifier. The Doherty power amplifier includes an input terminal configured to receive a radio frequency input signal, a carrier amplifier configured to amplify the radio frequency input signal and having a non-inverted carrier output and an inverted carrier output, a peaking amplifier configured to amplify the radio frequency input signal and having a non-inverted peaking output and an inverted peaking output, and an impedance inverter including a first series inductor having a first end electrically connected to the inverted carrier output and a second end electrically connected to the inverted peaking output, a second series inductor having a first end electrically connected to the non-inverted carrier output and a second end electrically connected to the non-inverted peaking output, a first cross capacitor electrically connected between the first end of the first series inductor and the second end of the second series inductor, and a second cross capacitor electrically connected between the first end of the second series inductor and the second end of the first series inductor.

In various embodiments, the first series inductor is electromagnetically coupled to the second series inductor to provide a mutual inductance.

In some embodiments, the Doherty power amplifier further includes an output balun having a primary winding electrically connected between the non-inverted peaking output and the inverted peaking output. In accordance with a number of embodiments, a secondary winding of the output balun is electrically connected between a radio frequency output terminal and a ground voltage, the radio frequency output terminal providing a radio frequency output signal that is amplified relative to the radio frequency input signal.

In several embodiments, the impedance inverter includes two or more stages, a first stage of the two or more stages including the first series inductor, the second series inductor, the first cross capacitor, and the second cross capacitor. In accordance with a number of embodiments, a second stage of the two or more stages includes a third series inductor having a first end electrically connected to the second end of the first series inductor and a second end electrically connected to the inverted peaking output, a fourth series inductor having a first end electrically connected to the second end of the second series inductor and a second end electrically connected to the non-inverted peaking output, a third cross capacitor electrically connected between the first end of the third series inductor and the second end of the fourth series inductor, and a fourth cross capacitor electrically connected between the first end of the fourth series inductor and the second end of the third series inductor.

In various embodiments, the Doherty power amplifier is implemented on a radio frequency module including a module substrate and a semiconductor die attached to the module substrate, the carrier amplifier and the peaking amplifier formed on the semiconductor die. According to a number of embodiments, the first cross capacitor and the second cross capacitor are formed on the semiconductor die, and the first series inductor and the second series inductor are formed as surface mount components attached to the module substrate.

In several embodiments, the carrier amplifier receives the radio frequency input signal, the Doherty power amplifier further comprising an input phase shifter configured to receive the radio frequency input signal and to provide a delay radio frequency input signal to the peaking amplifier, the radio frequency input signal and the delayed radio frequency input signal having a phase shift of about ninety degrees.

In some embodiments, the carrier amplifier includes a first carrier bipolar transistor having a collector electrically connected to the non-inverted carrier output and a second carrier bipolar transistor having a collector electrically connected to the inverted carrier output, the peaking amplifier including a first peaking bipolar transistor having a collector electrically connected to the non-inverted peaking output and a second peaking bipolar transistor having a collector electrically connected to the inverted peaking output. According to a number of embodiments, the carrier amplifier further includes a carrier balun having a secondary winding electrically connected between a base of the first carrier bipolar transistor and a base of the second carrier bipolar transistor, the peaking amplifier further including a peaking balun having a secondary winding electrically connected between a base of the first peaking bipolar transistor and a base of the second peaking bipolar transistor.

In various embodiments, the Doherty power amplifier is implemented to provide amplification for two or more frequency bands. According to a number of embodiments, the two or more frequency bands include n255 and n256.

In certain embodiments, a method of radio frequency signal amplification in a mobile device is disclosed. The method includes receiving a radio frequency input signal at an input terminal, amplifying the radio frequency input signal to generate a carrier signal using a carrier amplifier having a non-inverted carrier output and an inverted carrier output;

amplifying the radio frequency input signal to generate a peaking signal using a peaking amplifier having a non-inverted peaking output and an inverted peaking output, and combining the carrier signal and the peaking signal using an impedance inverter that includes a first series inductor having a first end electrically connected to the inverted carrier output and a second end electrically connected to the inverted peaking output, a second series inductor having a first end electrically connected to the non-inverted carrier output and a second end electrically connected to the non-inverted peaking output, a first cross capacitor electrically connected between the first end of the first series inductor and the second end of the second series inductor, and a second cross capacitor electrically connected between the first end of the second series inductor and the second end of the first series inductor.

In various embodiments, the first series inductor is electromagnetically coupled to the second series inductor to provide a mutual inductance.

In several embodiments, the method further includes coupling a primary winding of an output balun between the non-inverted peaking output and the inverted peaking output. According to a number of embodiments, the method further includes coupling a secondary winding of the output balun between a radio frequency output terminal and a ground voltage, the radio frequency output terminal providing a radio frequency output signal that is amplified relative to the radio frequency input signal. In accordance with some embodiments, the method further includes transmitting the radio frequency output signal using an antenna.

In various embodiments, the impedance inverter includes two or more stages, a first stage of the two or more stages including the first series inductor, the second series inductor, the first cross capacitor, and the second cross capacitor. In accordance with a number of embodiments, a second stage of the two or more stages includes a third series inductor having a first end electrically connected to the second end of the first series inductor and a second end electrically connected to the inverted peaking output, a fourth series inductor having a first end electrically connected to the second end of the second series inductor and a second end electrically connected to the non-inverted peaking output, a third cross capacitor electrically connected between the first end of the third series inductor and the second end of the fourth series inductor, and a fourth cross capacitor electrically connected between the first end of the fourth series inductor and the second end of the third series inductor.

In several embodiments, the method further includes using the carrier amplifier and the peaking amplifier to provide amplification for two or more frequency bands. In accordance with a number of embodiments, the two or more frequency bands include n255 and n256.

In certain embodiments, the present disclosure relates to a Doherty power amplifier. The Doherty power amplifier includes an input terminal configured to receive a radio frequency input signal, a carrier amplifier configured to amplify the radio frequency input signal and having a non-inverted carrier output and an inverted carrier output, a peaking amplifier configured to amplify the radio frequency input signal and having a non-inverted peaking output and an inverted peaking output, and an impedance inverter including a first series capacitor having a first end electrically connected to the inverted carrier output and a second end electrically connected to the inverted peaking output, a second series capacitor having a first end electrically connected to the non-inverted carrier output and a second end electrically connected to the non-inverted peaking output, a first cross inductor electrically connected between the first end of the first series capacitor and the second end of the second series capacitor, and a second cross inductor electrically connected between the first end of the second series capacitor and the second end of the first series capacitor.

In various embodiments, the first cross inductor is electromagnetically coupled to the second cross inductor to provide a mutual inductance.

In some embodiments, the Doherty power amplifier further includes an output balun having a primary winding electrically connected between the non-inverted peaking output and the inverted peaking output. According to a number of embodiments, a secondary winding of the output balun is electrically connected between a radio frequency output terminal and a ground voltage, the radio frequency output terminal providing a radio frequency output signal that is amplified relative to the radio frequency input signal.

In various embodiments, the impedance inverter includes two or more stages, a first stage of the two or more stages including the first series capacitor, the second series capacitor, the first cross inductor, and the second cross inductor. According to a number of embodiments, a second stage of the two or more stages includes a third series capacitor having a first end electrically connected to the second end of the first series capacitor and a second end electrically connected to the inverted peaking output, a fourth series capacitor having a first end electrically connected to the second end of the second series capacitor and a second end electrically connected to the non-inverted peaking output, a third cross inductor electrically connected between the first end of the third series capacitor and the second end of the fourth series capacitor, and a fourth cross inductor electrically connected between the first end of the fourth series capacitor and the second end of the third series capacitor.

In various embodiments, the Doherty power amplifier is implemented on a radio frequency module including a module substrate and a semiconductor die attached to the module substrate, the carrier amplifier and the peaking amplifier formed on the semiconductor die. According to a number of embodiments, the carrier amplifier receives the radio frequency input signal, the Doherty power amplifier further comprising an input phase shifter configured to receive the radio frequency input signal and to provide a delay radio frequency input signal to the peaking amplifier, the radio frequency input signal and the delayed radio frequency input signal having a phase shift of about ninety degrees.

In some embodiments, the carrier amplifier includes a first carrier bipolar transistor having a collector electrically connected to the non-inverted carrier output and a second carrier bipolar transistor having a collector electrically connected to the inverted carrier output, the peaking amplifier including a first peaking bipolar transistor having a collector electrically connected to the non-inverted peaking output and a second peaking bipolar transistor having a collector electrically connected to the inverted peaking output. According to a number of embodiments, the carrier amplifier further includes a carrier balun having a secondary winding electrically connected between a base of the first carrier bipolar transistor and a base of the second carrier bipolar transistor, the peaking amplifier further including a peaking balun having a secondary winding electrically connected between a base of the first peaking bipolar transistor and a base of the second peaking bipolar transistor.

In various embodiments, the Doherty power amplifier is implemented to provide amplification for two or more frequency bands. In accordance with several embodiments, the two or more frequency bands include n255 and n256.

In certain embodiments, a method of radio frequency signal amplification in a mobile device is disclosed. The method includes receiving a radio frequency input signal at an input terminal, amplifying the radio frequency input signal to generate a carrier signal using a carrier amplifier having a non-inverted carrier output and an inverted carrier output, amplifying the radio frequency input signal to generate a peaking signal using a peaking amplifier having a non-inverted peaking output and an inverted peaking output, and combining the carrier signal and the peaking signal using an impedance inverter that includes a first series capacitor having a first end electrically connected to the inverted carrier output and a second end electrically connected to the inverted peaking output, a second series capacitor having a first end electrically connected to the non-inverted carrier output and a second end electrically connected to the non-inverted peaking output, a first cross inductor electrically connected between the first end of the first series capacitor and the second end of the second series capacitor, and a second cross inductor electrically connected between the first end of the second series capacitor and the second end of the first series capacitor.

In various embodiments, the first cross inductor is electromagnetically coupled to the second cross inductor to provide a mutual inductance.

In several embodiments, the method further includes coupling a primary winding of an output balun between the non-inverted peaking output and the inverted peaking output. According to a number of embodiments, the method further includes coupling a secondary winding of the output balun between a radio frequency output terminal and a ground voltage, the radio frequency output terminal providing a radio frequency output signal that is amplified relative to the radio frequency input signal. In accordance with various embodiments, the method further includes transmitting the radio frequency output signal on an antenna.

In some embodiments, the impedance inverter includes two or more stages, a first stage of the two or more stages including the first series capacitor, the second series capacitor, the first cross inductor, and the second cross inductor. In accordance with several embodiments, a second stage of the two or more stages includes a third series capacitor having a first end electrically connected to the second end of the first series capacitor and a second end electrically connected to the inverted peaking output, a fourth series capacitor having a first end electrically connected to the second end of the second series capacitor and a second end electrically connected to the non-inverted peaking output, a third cross inductor electrically connected between the first end of the third series capacitor and the second end of the fourth series capacitor, and a fourth cross inductor electrically connected between the first end of the fourth series capacitor and the second end of the third series capacitor.

In various embodiments, the method further includes using the carrier amplifier and the peaking amplifier to provide amplification for two or more frequency bands. In accordance with a number of embodiments, the two or more frequency bands include n255 and n256.

In certain embodiments, the present disclosure relates to a mobile device. The mobile device includes a transceiver configured to generate a radio frequency input signal, and a front-end system including a Doherty power amplifier configured to amplify the radio frequency input signal. The Doherty power amplifier includes a carrier amplifier having a non-inverted carrier output and an inverted carrier output, a peaking amplifier having a non-inverted peaking output and an inverted peaking output, and an impedance inverter including a first series capacitor having a first end electrically connected to the inverted carrier output and a second end electrically connected to the inverted peaking output, a second series capacitor having a first end electrically connected to the non-inverted carrier output and a second end electrically connected to the non-inverted peaking output, a first cross inductor electrically connected between the first end of the first series capacitor and the second end of the second series capacitor, and a second cross inductor electrically connected between the first end of the second series capacitor and the second end of the first series capacitor.

In various embodiments, the first cross inductor is electromagnetically coupled to the second cross inductor to provide a mutual inductance.

In some embodiments, the Doherty power amplifier further includes an output balun having a primary winding electrically connected between the non-inverted peaking output and the inverted peaking output. According to a number of embodiments, a secondary winding of the output balun is electrically connected between a radio frequency output terminal and a ground voltage, the radio frequency output terminal providing a radio frequency output signal that is amplified relative to the radio frequency input signal. In accordance with several embodiments, the mobile device further includes an antenna configured to transmit the radio frequency output signal.

In various embodiments, the impedance inverter includes two or more stages, a first stage of the two or more stages including the first series capacitor, the second series capacitor, the first cross inductor, and the second cross inductor. In accordance with a number of embodiments, a second stage of the two or more stages includes a third series capacitor having a first end electrically connected to the second end of the first series capacitor and a second end electrically connected to the inverted peaking output, a fourth series capacitor having a first end electrically connected to the second end of the second series capacitor and a second end electrically connected to the non-inverted peaking output, a third cross inductor electrically connected between the first end of the third series capacitor and the second end of the fourth series capacitor, and a fourth cross inductor electrically connected between the first end of the fourth series capacitor and the second end of the third series capacitor.

In some embodiments, the front-end system includes a radio frequency module including a module substrate and a semiconductor die attached to the module substrate, the carrier amplifier and the peaking amplifier formed on the semiconductor die.

In various embodiments, the carrier amplifier receives the radio frequency input signal, the Doherty power amplifier further including an input phase shifter configured to receive the radio frequency input signal and to provide a delay radio frequency input signal to the peaking amplifier, the radio frequency input signal and the delayed radio frequency input signal having a phase shift of about ninety degrees.

In several embodiments, the carrier amplifier includes a first carrier bipolar transistor having a collector electrically connected to the non-inverted carrier output and a second carrier bipolar transistor having a collector electrically connected to the inverted carrier output, the peaking amplifier including a first peaking bipolar transistor having a collector electrically connected to the non-inverted peaking output and a second peaking bipolar transistor having a collector electrically connected to the inverted peaking output. According to a number of embodiments, the carrier amplifier further includes a carrier balun having a secondary winding electrically connected between a base of the first carrier bipolar transistor and a base of the second carrier bipolar transistor, the peaking amplifier further including a peaking balun having a secondary winding electrically connected between a base of the first peaking bipolar transistor and a base of the second peaking bipolar transistor.

In various embodiments, the Doherty power amplifier provides amplification for two or more frequency bands. According to a number of embodiments, the two or more frequency bands include n255 and n256.

### BRIEF DESCRIPTION OF THE DRAWINGS

Embodiments of this disclosure will now be described, by way of non-limiting example, with reference to the accompanying drawings.

FIG. 1 is a schematic diagram of one example of a communication network.

FIG. 2 is a schematic diagram of a Doherty power amplifier according to one embodiment.

FIG. 3 is a schematic diagram of a Doherty power amplifier according to another embodiment.

FIG. 4A is a schematic diagram of a radio frequency (RF) module according to one embodiment.

FIG. 4B is a plan view of a portion of the RF module of FIG. 4A.

FIG. 4C is a perspective view of a portion of the RF module of FIG. 4A.

FIG. 5A is a schematic diagram of a Doherty power amplifier according to another embodiment.

FIG. 5B is a schematic diagram of a Doherty power amplifier according to another embodiment.

FIG. 6 is a schematic diagram of a Doherty power amplifier according to another embodiment.

FIG. 7A is a schematic diagram of a Doherty power amplifier according to another embodiment.

FIG. 7B is a schematic diagram of a Doherty power amplifier according to another embodiment.

FIG. 8 is a graph of output power versus frequency for one example of a Doherty power amplifier.

FIG. 9A is one example of a smith chart for a non-inverted output of a carrier amplifier.

FIG. 9B is one example of a smith chart for an inverted output of a carrier amplifier.

FIG. 9C is one example of a smith chart for a non-inverted output of a peaking amplifier.

FIG. 9D is one example of a smith chart for an inverted output of a peaking amplifier.

FIG. 10 is a schematic diagram of one embodiment of a mobile device.

### DETAILED DESCRIPTION OF CERTAIN EMBODIMENTS

The following detailed description of certain embodiments presents various descriptions of specific embodiments. However, the innovations described herein can be embodied in a multitude of different ways, for example, as defined and covered by the claims. In this description, reference is made to the drawings where like reference numerals can indicate identical or functionally similar elements. It will be understood that elements illustrated in the figures are not necessarily drawn to scale. Moreover, it will be understood that certain embodiments can include more elements than illustrated in a drawing and/or a subset of the elements illustrated in a drawing. Further, some embodiments can incorporate any suitable combination of features from two or more drawings.

The International Telecommunication Union (ITU) is a specialized agency of the United Nations (UN) responsible for global issues concerning information and communication technologies, including the shared global use of radio spectrum.

The 3rd Generation Partnership Project (3GPP) is a collaboration between groups of telecommunications standard bodies across the world, such as the Association of Radio Industries and Businesses (ARIB), the Telecommunications Technology Committee (TTC), the China Communications Standards Association (CCSA), the Alliance for Telecommunications Industry Solutions (ATIS), the Telecommunications Technology Association (TTA), the European Telecommunications Standards Institute (ETSI), and the Telecommunications Standards Development Society, India (TSDSI).

Working within the scope of the ITU, 3GPP develops and maintains technical specifications for a variety of mobile communication technologies, including, for example, second generation (2G) technology (for instance, Global System for Mobile Communications (GSM) and Enhanced Data Rates for GSM Evolution (EDGE)), third generation (3G) technology (for instance, Universal Mobile Telecommunications System (UMTS) and High Speed Packet Access (HSPA)), and fourth generation (4G) technology (for instance, Long Term Evolution (LTE) and LTE-Advanced).

The technical specifications controlled by 3GPP can be expanded and revised by specification releases, which can span multiple years and specify a breadth of new features and evolutions.

In one example, 3GPP introduced carrier aggregation (CA) for LTE in Release 10. Although initially introduced with two downlink carriers, 3GPP expanded carrier aggregation in Release 14 to include up to five downlink carriers and up to three uplink carriers. Other examples of new features and evolutions provided by 3GPP releases include, but are not limited to, License Assisted Access (LAA), enhanced LAA (eLAA), Narrowband Internet of things (NB-IOT), Vehicle-to-Everything (V2X), and High Power User Equipment (HPUE).

3GPP introduced Phase 1 of fifth generation (5G) technology in Release 15, and introduced Phase 2 of 5G technology in Release 16. Subsequent 3GPP releases will further evolve and expand 5G technology. 5G technology is also referred to herein as 5G New Radio (NR).

5G NR supports or plans to support a variety of features, such as communications over millimeter wave spectrum, beamforming capability, high spectral efficiency waveforms, low latency communications, multiple radio numerology, and/or non-orthogonal multiple access (NOMA). Although such RF functionalities offer flexibility to networks and enhance user data rates, supporting such features can pose a number of technical challenges.

The teachings herein are applicable to a wide variety of communication systems, including, but not limited to, communication systems using advanced cellular technologies, such as LTE-Advanced, LTE-Advanced Pro, and/or 5G NR. Moreover, the teachings herein are applicable to non-terrestrial network (NTN) applications for supplementing terrestrial cellular communications.

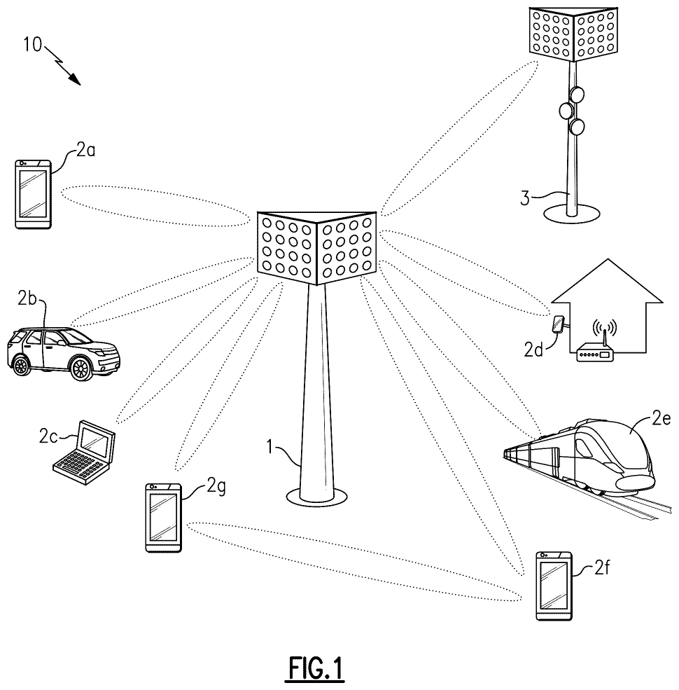

FIG. 1 is a schematic diagram of one example of a communication network 10. The communication network 10 includes a macro cell base station 1, a small cell base station 3, and various examples of user equipment (UE), including a first mobile device 2a, a wireless-connected car 2b, a laptop 2c, a stationary wireless device 2d, a wireless-connected train 2e, a second mobile device 2f, and a third mobile device 2g.

Although specific examples of base stations and user equipment are illustrated in FIG. 1, a communication network can include base stations and user equipment of a wide variety of types and/or numbers.

For instance, in the example shown, the communication network 10 includes the macro cell base station 1 and the small cell base station 3. The small cell base station 3 can operate with relatively lower power, shorter range, and/or with fewer concurrent users relative to the macro cell base station 1. The small cell base station 3 can also be referred to as a femtocell, a picocell, or a microcell. Although the communication network 10 is illustrated as including two base stations, the communication network 10 can be implemented to include more or fewer base stations and/or base stations of other types.

Although various examples of user equipment are shown, the teachings herein are applicable to a wide variety of user equipment, including, but not limited to, mobile phones, tablets, laptops, IoT devices, wearable electronics, customer premises equipment (CPE), wireless-connected vehicles, wireless relays, and/or a wide variety of other communication devices. Furthermore, user equipment includes not only currently available communication devices that operate in a cellular network, but also subsequently developed communication devices that will be readily implementable with the inventive systems, processes, methods, and devices as described and claimed herein.

The illustrated communication network 10 of FIG. 1 supports communications using a variety of cellular technologies, including, for example, 4G LTE and 5G NR. In certain implementations, the communication network 10 is further adapted to provide a wireless local area network (WLAN), such as WiFi. Although various examples of communication technologies have been provided, the communication network 10 can be adapted to support a wide variety of communication technologies.

Various communication links of the communication network 10 have been depicted in FIG. 1. The communication links can be duplexed in a wide variety of ways, including, for example, using frequency-division duplexing (FDD) and/or time-division duplexing (TDD). FDD is a type of radio frequency communications that uses different frequencies for transmitting and receiving signals. FDD can provide a number of advantages, such as high data rates and low latency. In contrast, TDD is a type of radio frequency communications that uses about the same frequency for transmitting and receiving signals, and in which transmit and receive communications are switched in time. TDD can provide a number of advantages, such as efficient use of spectrum and variable allocation of throughput between transmit and receive directions.

In certain implementations, user equipment can communicate with a base station using one or more of 4G LTE, 5G NR, and WiFi technologies. In certain implementations, enhanced license assisted access (eLAA) is used to aggregate one or more licensed frequency carriers (for instance, licensed 4G LTE and/or 5G NR frequencies), with one or more unlicensed carriers (for instance, unlicensed WiFi frequencies).

As shown in FIG. 1, the communication links include not only communication links between UE and base stations, but also UE to UE communications and base station to base station communications. For example, the communication network 10 can be implemented to support self-fronthaul and/or self-backhaul (for instance, as between mobile device 2g and mobile device 2f).

The communication links can operate over a wide variety of frequencies. For example, the communication links can serve Frequency Range 1 (FR1) in the range of about 410 MHz to about 7.125 GHz, Frequency Range 2 (FR2) in the range of about 24.250 GHz to about 52.600 GHz, or a combination thereof. In one embodiment, one or more of the mobile devices support a HPUE power class specification.

In certain implementations, a base station and/or user equipment communicates using beamforming. For example, beamforming can be used to focus signal strength to overcome path losses, such as high loss associated with communicating over high signal frequencies. In certain embodiments, user equipment, such as one or more mobile phones, communicate using beamforming on millimeter wave frequency bands in the range of 30 GHz to 300 GHz and/or upper centimeter wave frequencies in the range of 6 GHz to 30 GHz, or more particularly, 24 GHz to 30 GHz. Cellular user equipment can communicate using beamforming and/or other techniques over a wide range of frequencies, including, for example, FR2-1 (24 GHz to 52 GHz), FR2-2 (52 GHz to 71 GHz), and/or FR1 (400 MHz to 7125 MHz).

Different users of the communication network 10 can share available network resources, such as available frequency spectrum, in a wide variety of ways.

In one example, frequency division multiple access (FDMA) is used to divide a frequency band into multiple frequency carriers. Additionally, one or more carriers are allocated to a particular user. Examples of FDMA include, but are not limited to, single carrier FDMA (SC-FDMA) and orthogonal FDMA (OFDMA). OFDMA is a multicarrier technology that subdivides the available bandwidth into multiple mutually orthogonal narrowband subcarriers, which can be separately assigned to different users.

Other examples of shared access include, but are not limited to, time division multiple access (TDMA) in which a user is allocated particular time slots for using a frequency resource, code division multiple access (CDMA) in which a frequency resource is shared amongst different users by assigning each user a unique code, space-divisional multiple access (SDMA) in which beamforming is used to provide shared access by spatial division, and non-orthogonal multiple access (NOMA) in which the power domain is used for multiple access. For example, NOMA can be used to serve multiple users at the same frequency, time, and/or code, but with different power levels.

Enhanced mobile broadband (eMBB) refers to technology for growing system capacity of LTE networks. For example, eMBB can refer to communications with a peak data rate of at least 10 Gbps and a minimum of 100 Mbps for each user. Ultra-reliable low latency communications (uRLLC) refers to technology for communication with very low latency, for instance, less than 2 milliseconds. uRLLC can be used for mission-critical communications such as for autonomous driving and/or remote surgery applications. Massive machine-type communications (mMTC) refers to low cost and low data rate communications associated with wireless connections to everyday objects, such as those associated with Internet of Things (IoT) applications.

The communication network 10 of FIG. 1 can be used to support a wide variety of advanced communication features, including, but not limited to, eMBB, uRLLC, and/or mMTC.

Doherty Power Amplifiers with Inductor-Capacitor Lattice for Impedance Inversion

One type of power amplifier is a Doherty power amplifier, which includes a main or carrier amplifier and an auxiliary or peaking amplifier that operate in combination with one another to amplify an RF signal. The Doherty power amplifier includes an impedance inverter that combines a carrier signal from the carrier amplifier and a peaking signal from the peaking amplifier to generate an amplified RF output signal. In certain implementations, the carrier amplifier is enabled over a wide range of power levels (for instance, by a class AB bias circuit) while the peaking amplifier is selectively enabled (for instance, by a class C bias circuit) at high power levels.

The linearity of a Doherty power amplifier is directly related to a level of gain compression within the power amplifier. Thus, a Doherty power amplifier can be designed for a fixed supply voltage that defines the target load impedance for acceptable linearity.

Doherty power amplifiers can provide high power added efficiency (PAE) and/or high linearity.

However, conventional Doherty power amplifiers face significant limitations related to bandwidth. For example, the impedance inverter of a Doherty power amplifier can be a primary factor in limiting the bandwidth as evident when examining the impedances presented to the carrier amplifier at peak power and at back-off power. For example, when the impedance inverter is implemented using quarter wavelength (λ/4) transmission lines, the characteristic impedances of the λ/4 transmission lines provide a significant contribution to this bandwidth limitation. Moreover, in many mobile handset applications, λ/4 transmission lines are implemented using lumped elements, which leads to a further degradation in bandwidth.

The bandwidth limitations of Doherty power amplifiers pose a challenge to achieving the desired performance and efficiency levels required for modern communication systems, including 5G and/or NTN networks.

Doherty power amplifiers with an inductor-capacitor (LC) lattice for impedance inversion are disclosed. In certain embodiments, a Doherty power amplifier includes a carrier amplifier, a peaking amplifier, and an LC lattice that serves as an impedance inverter for combining a differential carrier signal from the carrier amplifier with a differential peaking signal from the peaking amplifier. The LC lattice can include series inductors and cross capacitors connected to form a lattice, or series capacitors and cross inductors connected to form the lattice.

Accordingly, a lattice structure of inductor and capacitor components is used to implement the impedance inverter of a Doherty power amplifier.

By integrating the lattice structure into the Doherty power combining network, broadband operation of the Doherty power amplifier is achieved. Furthermore, such a Doherty power amplifier can maintain high efficiency and linearity.

Moreover, the bandwidth improvement enables a single Doherty power amplifier to support wideband operation covering two or more frequency bands, thereby eliminating a need for multiple band power amplifiers for certain applications. As a result, the compact size of the power amplifier is maintained, leading to cost savings in both manufacturing and integration processes. For instance, the Doherty power amplifiers herein can be used for 5G and/or NTN applications covering two or more frequency bands. In one example, a single Doherty power amplifier for a mobile device provides amplification for both an n255 frequency band (1626.5 MHz to 1660.5 MHz uplink) and an n256 frequency band (1980 MHz to 2010 MHz uplink).

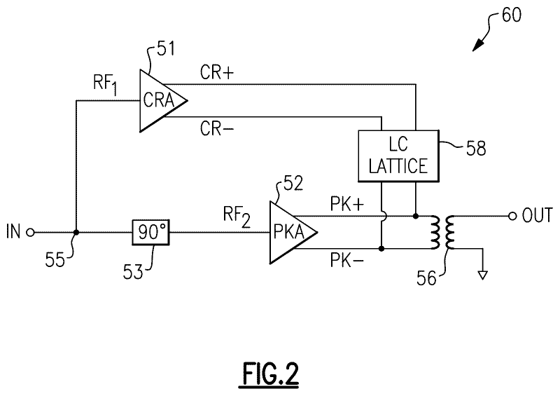

FIG. 2 is a schematic diagram of a Doherty power amplifier 60 according to one embodiment. The Doherty power amplifier 60 includes a carrier amplifier 51, a peaking amplifier 52, an input phase shifter 53, an output balun 56, and an impedance inverter 58 with an LC lattice structure.

Although one embodiment of a Doherty power amplifier is shown, the teachings herein are applicable to Doherty power amplifiers implemented in a wide variety of ways.

As shown in FIG. 2, the Doherty power amplifier 60 includes a node 55 that splits an RF input signal received at an input terminal RF_IN into a first RF input signal RF₁ for the carrier amplifier 51 and a replica of the first RF input signal for the input phase shifter 53. Although the node 55 is depicted as splitting the RF input signal, any signal splitting structure can be used. The replica of the first RF input signal is phase-shifted by the phase shifter 53 (by about ninety degrees, in this example) to generate the second RF input signal RF₂. Although an example using an explicit input phase shifter is shown, other implementations are possible. In one example, a 3 dB or hybrid coupler can be used to split the RF signal into a pair of signals having a phase difference of about ninety degrees.

The carrier amplifier 51 amplifies the first RF input signal RF₁ to generate a differential carrier signal between a non-inverted carrier output CR+ and an inverted carrier output CR−. Additionally, the peaking amplifier 52 amplifies the second RF input signal RF₂ to generate a differential peaking signal between a non-inverted peaking output PK+ and an inverted peaking output PK−.

As shown in FIG. 2, the output balun 56 includes a primary winding electrically connected between the non-inverted peaking output PK+ and the inverted peaking output PK−, and a secondary winding electrically connected between the output terminal OUT and a ground voltage. The output terminal OUT provides an RF output signal that is amplified relative to the RF input signal.

The impedance inverter 58 combines the carrier signal from the carrier amplifier 51 with the peaking signal from the peaking amplifier 52 while providing proper impedance and phase-shifting.

In the illustrated embodiment, the impedance inverter 58 is implemented with an inductor-capacitor lattice structure in accordance with the teachings herein.

By implementing the impedance inverter 58 in this manner, wide bandwidth operation is achieved. For instance, the Doherty power amplifier 60 can be suitable for amplifying wide bandwidth signals and/or amplifying two or more RF signals associated with different frequency bands. In one example, the Doherty power amplifier 60 provides amplification for uplink for both an n255 frequency band and an n256 frequency band for an NTN application. The Doherty power amplifier 60 can operate with wide bandwidth to accommodate two or more frequency bands while maintaining high efficiency and linearity.

In certain implementations, a band switch can be included at the input terminal IN for providing a selected RF signal associated with a particular frequency band to the Doherty power amplifier 60 for amplification.

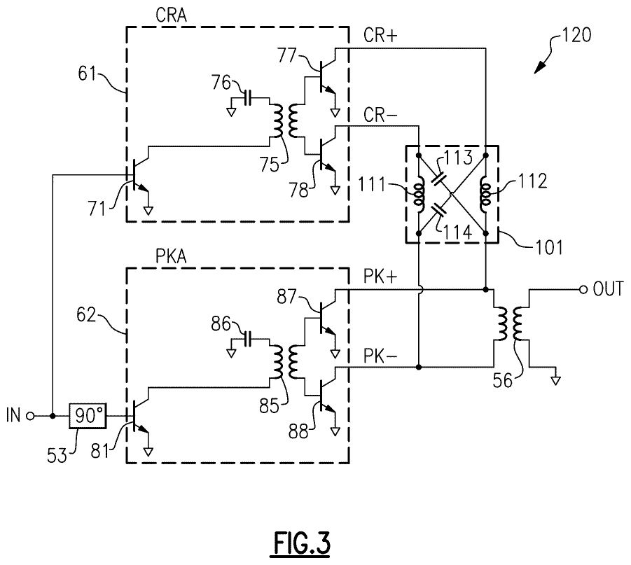

FIG. 3 is a schematic diagram of a Doherty power amplifier 120 according to another embodiment. The Doherty power amplifier 120 includes a carrier amplifier 61, a peaking amplifier 62, an input phase shifter 53, an output balun 56, and an impedance inverter 101 implemented as an LC lattice.

The Doherty power amplifier 120 of FIG. 3 is similar to the Doherty power amplifier of FIG. 2, except that the Doherty power amplifier 120 of FIG. 3 depicts a specific implementation of the carrier amplifier 61, the peaking amplifier 62, and the impedance inverter 101. Although another embodiment of a Doherty power amplifier is shown in FIG. 3, the teachings herein are applicable to Doherty power amplifiers implemented in a wide variety of ways.

In the illustrated embodiment, the carrier amplifier 61 includes an input bipolar transistor 71, a balun 75, a balun termination capacitor 76, a first output bipolar transistor 77, and a second output bipolar transistor 78. Additionally, the input bipolar transistor 71 includes a base electrically connected to the input terminal IN, an emitter electrically connected to the ground voltage, and a collector electrically connected to a first end of a primary winding of the balun 75. The balun termination capacitor 76 is electrically connected between a second end of the primary winding of the balun 75 and the ground voltage. Additionally, a secondary winding of the balun 75 is electrically connected between a base of the first output bipolar transistor 77 and a base of the second output bipolar transistor 78. The emitters of the first output bipolar transistor 77 and the second output bipolar transistor 78 are electrically connected to the ground voltage (ground). The collector of the first output bipolar transistor 77 serves as a non-inverted carrier output CR+, while the collector of the second output bipolar transistor 78 serves as an inverted carrier output CR−.

With continuing reference to FIG. 3, the peaking amplifier 62 includes an input bipolar transistor 81, a balun 85, a balun termination capacitor 86, a first output bipolar transistor 87, and a second output bipolar transistor 88. Additionally, the input bipolar transistor 81 includes a base electrically connected to the output of the input phase shifter 53, an emitter electrically connected to the ground voltage, and a collector electrically connected to a first end of a primary winding of the balun 85. The balun termination capacitor 86 is electrically connected between a second end of the primary winding of the balun 85 and the ground voltage. Additionally, a secondary winding of the balun 85 is electrically connected between a base of the first output bipolar transistor 87 and a base of the second output bipolar transistor 88. The emitters of the first output bipolar transistor 87 and the second output bipolar transistor 88 are electrically connected to the ground voltage. The collector of the first output bipolar transistor 87 serves as a non-inverted peaking output PK+, while the collector of the second output bipolar transistor 88 serves as an inverted peaking output PK−.

In the illustrated embodiment, the impedance inverter 101 includes a first series inductor 111, a second series inductor 112, a first cross capacitor 113, and a second cross capacitor 114 electrically connected to form an LC lattice.

For example, as shown in FIG. 3, the first series inductor 111 includes a first end electrically connected to the inverted carrier output CR− and a second end electrically connected to the inverted peaking output PK−. Additionally, the second series inductor 112 includes a first end electrically connected to the non-inverted carrier output CR+ and a second end electrically connected to the non-inverted peaking output PK+. Furthermore, the first cross capacitor 113 is electrically connected between the first end of the first series inductor 111 and the second end of the second series inductor 112. Additionally, the second cross capacitor 114 is electrically connected between the first end of the second series inductor 112 and the second end of the first series inductor 111.

By implementing the impedance inverter using an LC lattice, enhanced bandwidth is achieved.

The inductors of the LC lattice can have the same or different inductance values, depending on implementation and/or operational characteristics of the carrier amplifier and the peaking amplifier. Additionally, the capacitors of the LC lattice can have the same or different capacitance values, depending on implementation and/or operational characteristics of the carrier amplifier and the peaking amplifier.

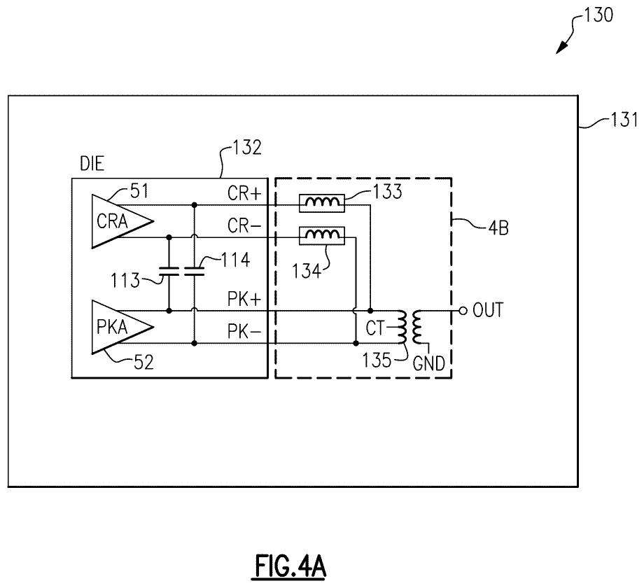

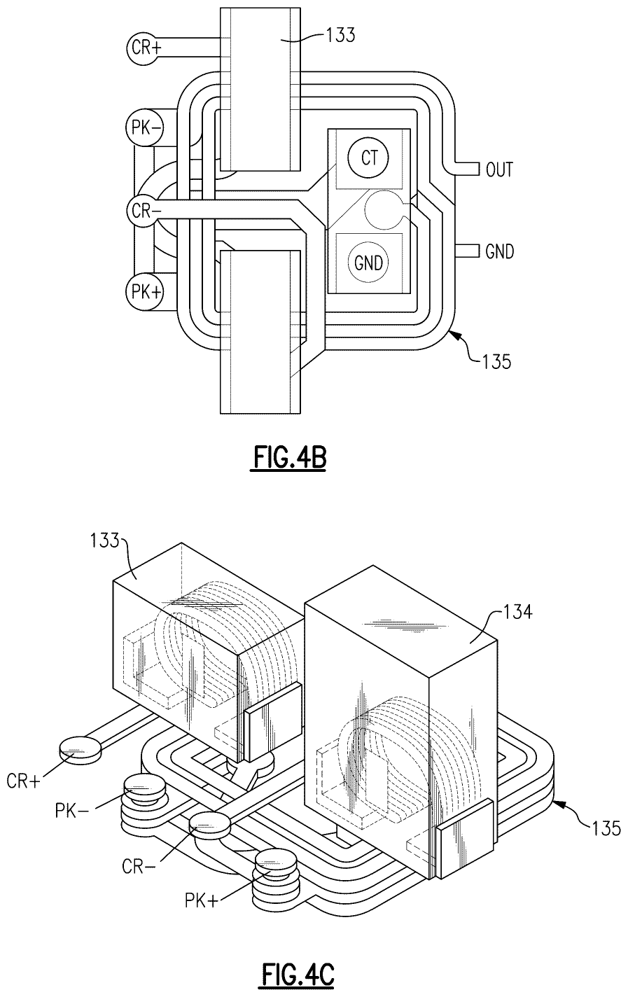

FIG. 4A is a schematic diagram of an RF module 130 according to one embodiment. FIG. 4B is a plan view of a portion 4B of the RF module 130 of FIG. 4A. FIG. 4C is a perspective view of the portion 4B of the RF module 130 of FIG. 4A.

The RF module 130 depicts one embodiment of an RF module that includes a Doherty power amplifier with an LC lattice for providing impedance inversion. However, the Doherty power amplifiers herein can be implemented on RF modules in other ways. Accordingly, other implementations are possible.

With reference to FIGS. 4A-4C, the RF module 130 includes a module substrate 131 to which a semiconductor die 132 is attached. Additionally, a first series inductor 133 and a second series inductor 134 are implemented as surface mount components attached to the module substrate 131 using surface mount technology (SMT). Furthermore, an output balun 135 is formed from patterned conductive layers of the module substrate 131.

In the illustrated embodiment, the semiconductor die 132 includes a carrier amplifier 51 having a non-inverted carrier output CR+ and an inverted carrier output CR−, a peaking amplifier 52 having a non-inverted peaking output PK+ and an inverted peaking output PK−, a first cross capacitor 113, and a second cross capacitor 114.

Accordingly, the cross capacitors of the impedance inverter are formed on-chip, in this embodiment.

As shown in FIGS. 4A-4C, the output balun 135 includes a primary winding electrically between the non-inverted peaking output PK+ and the inverted peaking output PK−. The primary winding of the output balun 135 also includes a center tap CT, which can connect to a power supply voltage to supply power to the carrier amplifier 51 and the peaking amplifier 52. The secondary winding of the output balun 135 is electrically connected between an output terminal OUT and a ground terminal GND for receiving ground.

In the illustrated embodiment, the first series inductor 133 and the second series inductor 134 are implemented in a side-by-side configuration in which the coils of the inductors 133/134 are aligned and run parallel to one another. Additionally, conductive shielding structures are included at the sides of the coils for each inductor to provide shielding.

By implementing the inductors 133/134 in this manner, isolation is achieved. However, the teachings herein are also applicable to configurations in which the first series inductor 133 is electromagnetically coupled to the second series inductor 134 to provide a mutual inductance. For example, the position and/or orientation between the inductors 133/134 can be selected to achieve a desired amount of electromagnetic coupling. Further, shielding structures can be removed to enhance coupling.

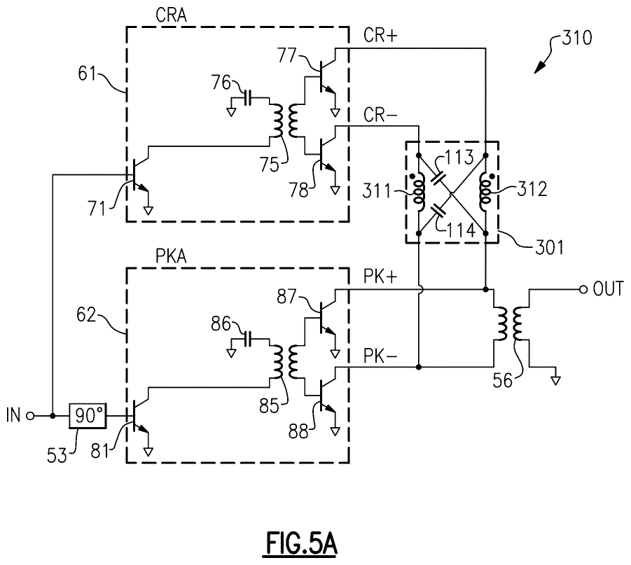

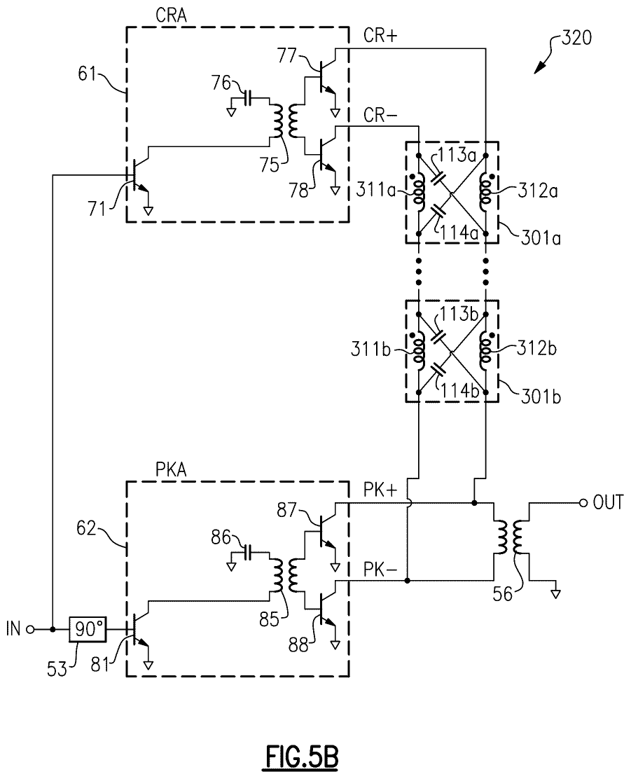

FIG. 5A is a schematic diagram of a Doherty power amplifier 310 according to another embodiment. The Doherty power amplifier 310 includes a carrier amplifier 61, a peaking amplifier 62, an input phase shifter 53, an output balun 56, and an impedance inverter 301.

The Doherty power amplifier 310 of FIG. 5A is similar to the Doherty power amplifier 120 of FIG. 3, except that the Doherty power amplifier 310 of FIG. 5A depicts a different implementation of an impedance inverter.

For example, the impedance inverter 301 includes a first series inductor 311, a second series inductor 312, a first cross capacitor 113, and a second cross capacitor 114 connected in an LC lattice similar to that of FIG. 3. However, in the embodiment of FIG. 5A, the first series inductor 311 is electromagnetically coupled to the second series inductor 312 to provide a mutual inductance M. In certain implementations, the mutual inductance M is about equal to k*√(L1+L2), where L1 is the inductance of the inductor 311, L2 is the inductance of the inductor 312, and k is a factor between −1 and 1.

FIG. 5B is a schematic diagram of a Doherty power amplifier 320 according to another embodiment. The Doherty power amplifier 320 includes a carrier amplifier 61, a peaking amplifier 62, an input phase shifter 53, an output balun 56, a first impedance inverter stage 301a, and a second impedance inverter stage 301b.

The Doherty power amplifier 320 of FIG. 5B is similar to the Doherty power amplifier 310 of FIG. 5A, except that the Doherty power amplifier 320 of FIG. 5B depicts a multi-stage implementation of an impedance inverter.

For example, the first impedance inverter stage 301a includes a first series inductor 311a, a second series inductor 311b (electromagnetically coupled to the inductor 311a, in this example), a first cross capacitor 113a, and a second cross capacitor 114a. Additionally, the second impedance inverter stage 301b includes a third series inductor 311b, a fourth series inductor 312b (electromagnetically coupled to the inductor 311b, in this example), a third cross capacitor 113b, and a fourth cross capacitor 114b.

Although an example of a two-stage impedance inverter is shown, an impedance inverter can be implemented with more than two stages as indicated by the ellipses.

Any of the impedance inverters herein can be implemented using two or more stages.

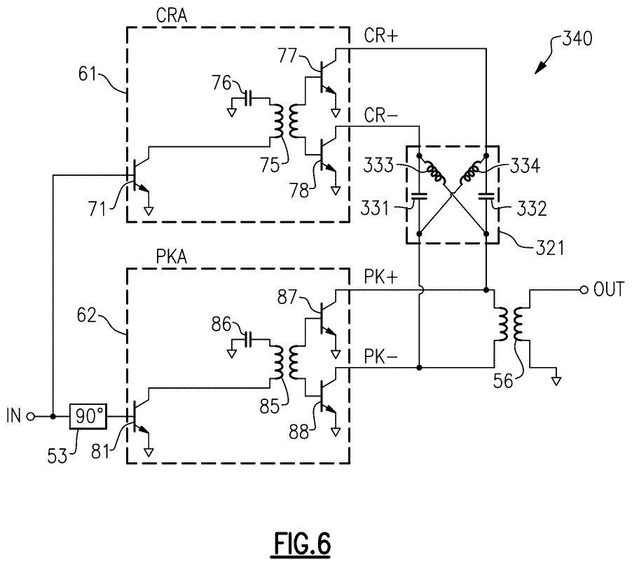

FIG. 6 is a schematic diagram of a Doherty power amplifier 340 according to another embodiment. The Doherty power amplifier 340 includes a carrier amplifier 61, a peaking amplifier 62, an input phase shifter 53, an output balun 56, and an impedance inverter 321.

The Doherty power amplifier 340 of FIG. 6 is similar to the Doherty power amplifier 310 of FIG. 5A, except that the Doherty power amplifier 340 of FIG. 6 depicts a different implementation of an impedance inverter.

For example, the impedance inverter 321 includes a first series capacitor 331, a second series capacitor 332, a first cross inductor 333, and a second cross inductor 334.

Additionally, the first series capacitor 331 includes a first end electrically connected to the inverted carrier output CR− and a second end electrically connected to the inverted peaking output PK−. Furthermore, the second series capacitor 332 includes a first end electrically connected to the non-inverted carrier output CR+ and a second end electrically connected to the non-inverted peaking output PK+. Additionally, the first cross inductor 333 is electrically connected between the first end of first series capacitor 331 and the second end of the second series capacitor 332. Furthermore, the second cross inductor 334 is electrically connected between the first end of the second series capacitor 332 and the second end of the first series capacitor 331.

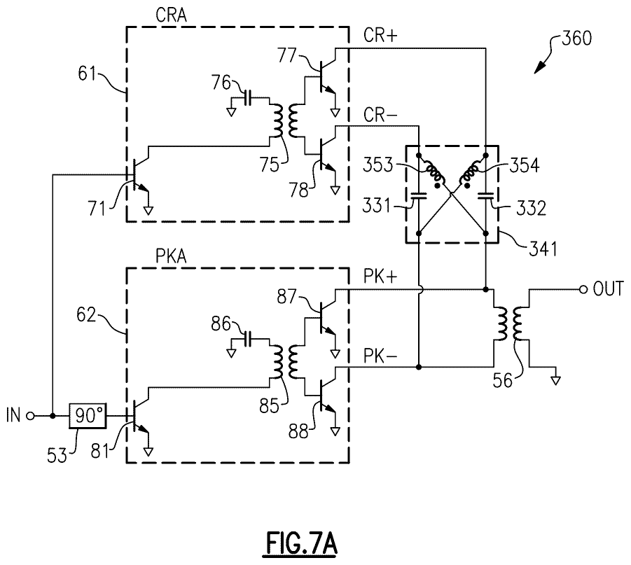

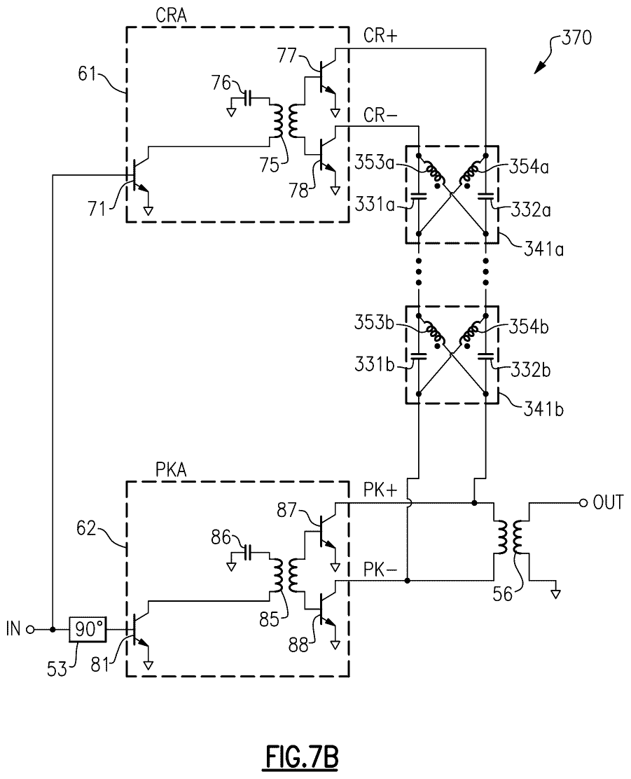

FIG. 7A is a schematic diagram of a Doherty power amplifier 360 according to another embodiment. The Doherty power amplifier 360 includes a carrier amplifier 61, a peaking amplifier 62, an input phase shifter 53, an output balun 56, and an impedance inverter 341.

The Doherty power amplifier 360 of FIG. 7A is similar to the Doherty power amplifier 340 of FIG. 6, except that the Doherty power amplifier 360 of FIG. 7A depicts a different implementation of an impedance inverter.

For example, the impedance inverter 341 includes a first series capacitor 331, a second series capacitor 332, a first cross inductor 353, and a second cross inductor 354 connected in a lattice similar to that of FIG. 6. However, in the embodiment of FIG. 7A, the first cross inductor 353 is electromagnetically coupled to the second cross inductor 354 to provide a mutual inductance M. In certain implementations, the mutual inductance M is about equal to k*√(L1+L2), where L1 is the inductance of the inductor 353, L2 is the inductance of the inductor 354, and k is a factor between −1 and 1.

FIG. 7B is a schematic diagram of a Doherty power amplifier 370 according to another embodiment. The Doherty power amplifier 370 includes a carrier amplifier 61, a peaking amplifier 62, an input phase shifter 53, an output balun 56, a first impedance inverter stage 341a, and a second impedance inverter stage 341b.

The Doherty power amplifier 370 of FIG. 7B is similar to the Doherty power amplifier 360 of FIG. 7A, except that the Doherty power amplifier 370 of FIG. 5B depicts a multi-stage implementation of an impedance inverter.

For example, the first impedance inverter stage 341a includes a first series capacitor 331a, a second series capacitor 332a, a first cross inductor 353a, and a second cross inductor 354a (electromagnetically coupled to the inductor 353a). Additionally, the second impedance inverter stage 341b includes a third series capacitor 331b, a fourth series capacitor 332b, a third cross inductor 353b, and a fourth cross inductor 354b (electromagnetically coupled to the inductor 353b).

Although an example of a two-stage impedance inverter is shown, an impedance inverter can be implemented with more than two stages as indicated by the ellipses.

Any of the impedance inverters herein can be implemented using two or more stages.

FIG. 8 is a graph of output power (in dBm) versus frequency (in GHz) for one example of a Doherty power amplifier. The graph includes plots of output power versus frequency for both a carrier amplifier and a peaking amplifier that have outputs combined using one implementation of an LC lattice. The output power characteristics depicts that the example Doherty power amplifier exhibits wide bandwidth.

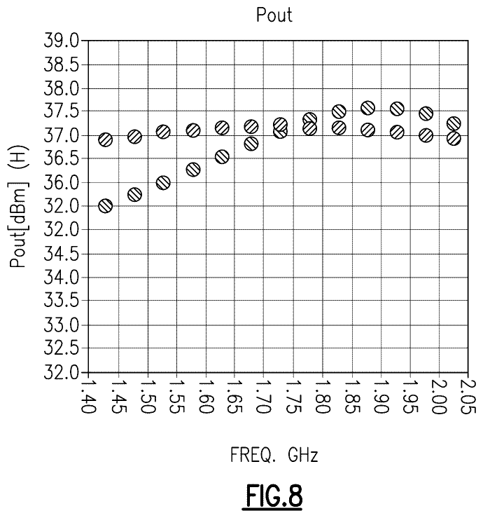

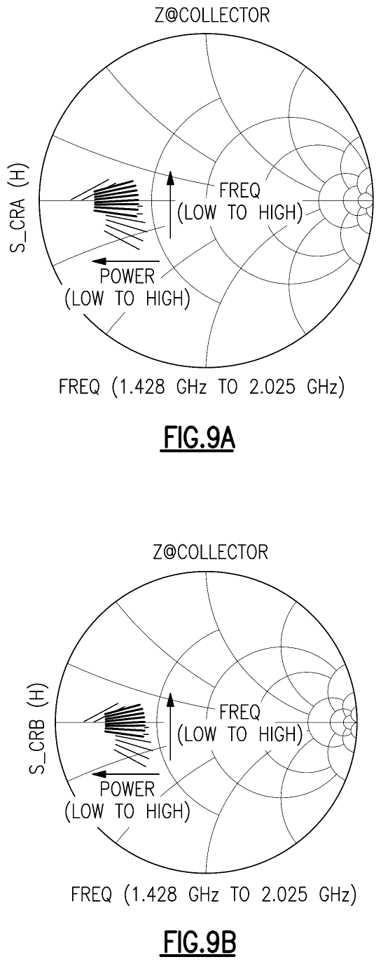

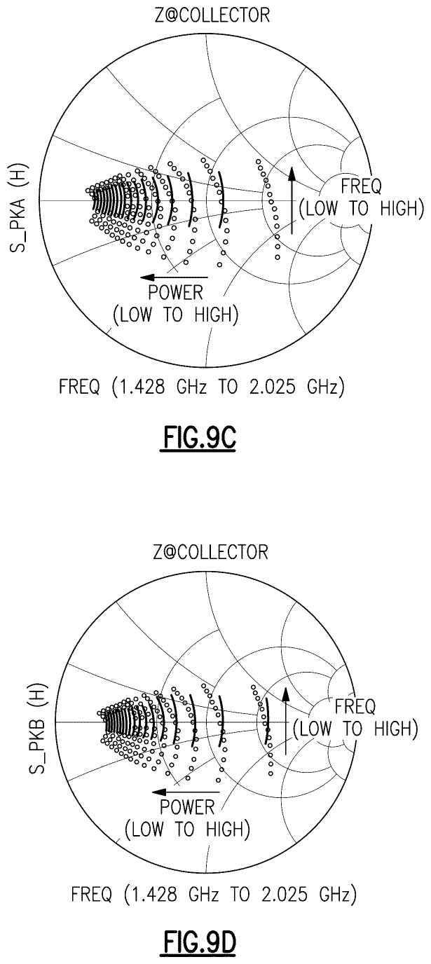

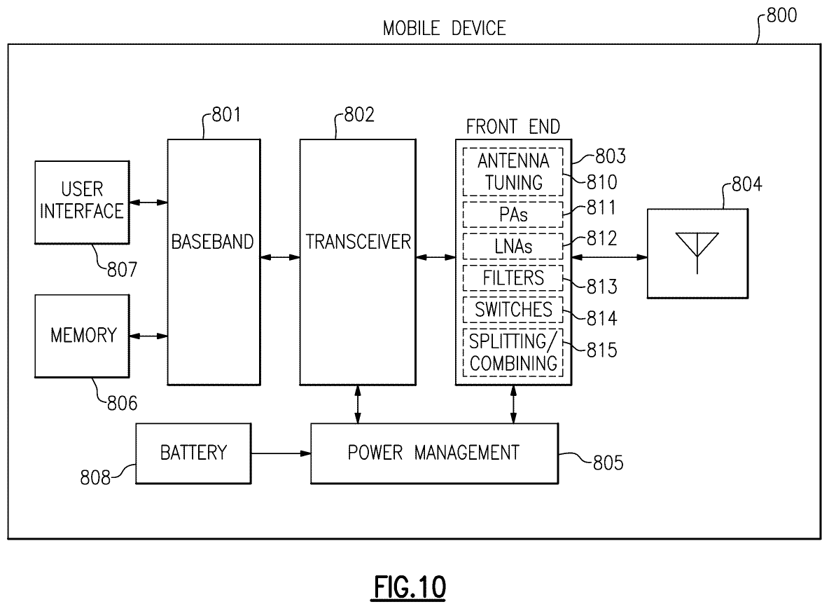

FIG. 9A is one example of a smith chart for a non-inverted output of a carrier amplifier. FIG. 9B is one example of a smith chart for an inverted output of a carrier amplifier. FIG. 9C is one example of a smith chart for a non-inverted output of a peaking amplifier. FIG. 9D is one example of a smith chart for an inverted output of a peaking amplifier.

With reference to FIGS. 9A-9D, the smith charts depict a first group of plots for a Doherty power amplifier implemented with an LC lattice (bolded plots) for impedance inversion and a second group of plots for a Doherty power amplifier implemented with 24 transmission lines (non-bolded plots) for impedance inversion. The smith charts are depicted for a frequency sweep from 1.428 GHz to 2.025 GHz as well as a sweep in output power from low power to high power.

As shown by a comparison of the bolded plots to the non-bolded plots, the Doherty power amplifier with LC lattice for impedance inversion provides much tighter operational range over frequency and output power. This tighter operational range leads to improved bandwidth and/or other operating characteristics.

FIG. 10 is a schematic diagram of one embodiment of a mobile device 800. The mobile device 800 includes a baseband system 801, a transceiver 802, a front-end system 803, antennas 804, a power management system 805, a memory 806, a user interface 807, and a battery 808.

The mobile device 800 can be used communicate using a wide variety of communications technologies, including, but not limited to, 2G, 3G, 4G (including LTE, LTE-Advanced, and LTE-Advanced Pro), 5G NR, NTN, WLAN (for instance, WiFi), WPAN (for instance, Bluetooth and ZigBee), WMAN (for instance, WiMax), and/or GPS technologies.

The transceiver 802 generates RF signals for transmission and processes incoming RF signals received from the antennas 804. It will be understood that various functionalities associated with the transmission and receiving of RF signals can be achieved by one or more components that are collectively represented in FIG. 10 as the transceiver 802. In one example, separate components (for instance, separate circuits or dies) can be provided for handling certain types of RF signals.

The front-end system 803 aids in conditioning signals transmitted to and/or received from the antennas 804. In the illustrated embodiment, the front-end system 803 includes antenna tuning circuitry 810, power amplifiers (PAs) 811, low noise amplifiers (LNAs) 812, filters 813, switches 814, and signal splitting/combining circuitry 815. However, other implementations are possible. The front-end system 803 (for example, the PAs 811) can include one or more Doherty power amplifiers implemented in accordance with the teachings herein.

Thus, the front-end system 803 can provide a number of functionalities, including, but not limited to, amplifying signals for transmission, amplifying received signals, filtering signals, switching between different bands, switching between different power modes, switching between transmission and receiving modes, duplexing of signals, multiplexing of signals (for instance, diplexing or triplexing), or some combination thereof.

In certain implementations, the mobile device 800 supports carrier aggregation, thereby providing flexibility to increase peak data rates. Carrier aggregation can be used for both Frequency Division Duplexing (FDD) and Time Division Duplexing (TDD), and may be used to aggregate a plurality of carriers or channels. Carrier aggregation includes contiguous aggregation, in which contiguous carriers within the same operating frequency band are aggregated. Carrier aggregation can also be non-contiguous and can include carriers separated in frequency within a common band or in different bands.

The antennas 804 can include antennas used for a wide variety of types of communications. For example, the antennas 804 can include antennas for transmitting and/or receiving signals associated with a wide variety of frequencies and communications standards.

In certain implementations, the antennas 804 support MIMO communications and/or switched diversity communications. For example, MIMO communications use multiple antennas for communicating multiple data streams over a single radio frequency channel. MIMO communications benefit from higher signal to noise ratio, improved coding, and/or reduced signal interference due to spatial multiplexing differences of the radio environment. Switched diversity refers to communications in which a particular antenna is selected for operation at a particular time. For example, a switch can be used to select a particular antenna from a group of antennas based on a variety of factors, such as an observed bit error rate and/or a signal strength indicator.

The mobile device 800 can operate with beamforming in certain implementations. For example, the front-end system 803 can include amplifiers having controllable gain and phase shifters having controllable phase to provide beam formation and directivity for transmission and/or reception of signals using the antennas 804. For example, in the context of signal transmission, the amplitude and phases of the transmit signals provided to the antennas 804 are controlled such that radiated signals from the antennas 804 combine using constructive and destructive interference to generate an aggregate transmit signal exhibiting beam-like qualities with more signal strength propagating in a given direction. In the context of signal reception, the amplitude and phases are controlled such that more signal energy is received when the signal is arriving to the antennas 804 from a particular direction. In certain implementations, the antennas 804 include one or more arrays of antenna elements to enhance beamforming.

The baseband system 801 is connected to the user interface 807 to facilitate processing of various user input and output (I/O), such as voice and data. The baseband system 801 provides the transceiver 802 with digital representations of transmit signals, which the transceiver 802 processes to generate RF signals for transmission. The baseband system 801 also processes digital representations of received signals provided by the transceiver 802. As shown in FIG. 10, the baseband system 801 is connected to the memory 806 of facilitate operation of the mobile device 800.

The memory 806 can be used for a wide variety of purposes, such as storing data and/or instructions to facilitate the operation of the mobile device 800 and/or to provide storage of user information.

The power management system 805 provides a number of power management functions of the mobile device 800. In certain implementations, the power management system 805 includes a PA supply control circuit that controls the supply voltages of the power amplifiers 811. For example, the power management system 805 can be configured to change the supply voltage(s) provided to one or more of the power amplifiers 811 to improve efficiency, such as power added efficiency (PAE).

As shown in FIG. 10, the power management system 805 receives a battery voltage from the battery 808. The battery 808 can be any suitable battery for use in the mobile device 800, including, for example, a lithium-ion battery.

### Applications

The principles and advantages of the embodiments herein can be used for any other systems or apparatus that have needs for RF amplification. Examples of such apparatus include RF communication systems. RF communications systems include, but are not limited to, mobile phones, tablets, base stations, network access points, customer-premises equipment (CPE), laptops, and wearable electronics. Thus, the RF combiners herein can be included in various electronic devices, including, but not limited to, consumer electronic products.

### CONCLUSION

Unless the context clearly requires otherwise, throughout the description and the claims, the words “comprise,” “comprising,” and the like are to be construed in an inclusive sense, as opposed to an exclusive or exhaustive sense; that is to say, in the sense of “including, but not limited to.” The word “connected”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively. The word “or” in reference to a list of two or more items, that word covers all of the following interpretations of the word: any of the items in the list, all of the items in the list, and any combination of the items in the list.

Moreover, conditional language used herein, such as, among others, “may,” “could,” “might,” “can,” “e.g.,” “for example,” “such as” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments or that one or more embodiments necessarily include logic for deciding, with or without author input or prompting, whether these features, elements and/or states are included or are to be performed in any particular embodiment.

The above detailed description of embodiments of the invention is not intended to be exhaustive or to limit the invention to the precise form disclosed above. While specific embodiments of, and examples for, the invention are described above for illustrative purposes, various equivalent modifications are possible within the scope of the invention, as those skilled in the relevant art will recognize. For example, while processes or blocks are presented in a given order, alternative embodiments may perform routines having steps, or employ systems having blocks, in a different order, and some processes or blocks may be deleted, moved, added, subdivided, combined, and/or modified. Each of these processes or blocks may be implemented in a variety of different ways. Also, while processes or blocks are at times shown as being performed in series, these processes or blocks may instead be performed in parallel or may be performed at different times.

The teachings of the invention provided herein can be applied to other systems, not necessarily the system described above. The elements and acts of the various embodiments described above can be combined to provide further embodiments.

While certain embodiments of the inventions have been described, these embodiments have been presented by way of example only and are not intended to limit the scope of the disclosure. Indeed, the novel methods and systems described herein may be embodied in a variety of other forms; furthermore, various omissions, substitutions and changes in the form of the methods and systems described herein may be made without departing from the spirit of the disclosure. The accompanying claims and their equivalents are intended to cover such forms or modifications as would fall within the scope and spirit of the disclosure.

1. A mobile device comprising:
a transceiver configured to generate a radio frequency input signal; and
a front-end system including a Doherty power amplifier configured to amplify the radio frequency input signal, the Doherty power amplifier including a carrier amplifier having a non-inverted carrier output and an inverted carrier output, a peaking amplifier having a non-inverted peaking output and an inverted peaking output, and an impedance inverter including a first series inductor having a first end electrically connected to the inverted carrier output and a second end electrically connected to the inverted peaking output, a second series inductor having a first end electrically connected to the non-inverted carrier output and a second end electrically connected to the non-inverted peaking output, a first cross capacitor electrically connected between the first end of the first series inductor and the second end of the second series inductor, and a second cross capacitor electrically connected between the first end of the second series inductor and the second end of the first series inductor.

2. The mobile device of claim 1 wherein the first series inductor is electromagnetically coupled to the second series inductor to provide a mutual inductance.

3. The mobile device of claim 1 wherein the Doherty power amplifier further includes an output balun having a primary winding electrically connected between the non-inverted peaking output and the inverted peaking output.

4. The mobile device of claim 3 wherein a secondary winding of the output balun is electrically connected between a radio frequency output terminal and a ground voltage, the radio frequency output terminal providing a radio frequency output signal that is amplified relative to the radio frequency input signal.

5. The mobile device of claim 1 wherein the impedance inverter includes two or more stages, a first stage of the two or more stages including the first series inductor, the second series inductor, the first cross capacitor, and the second cross capacitor.

6. The mobile device of claim 5 wherein a second stage of the two or more stages includes a third series inductor having a first end electrically connected to the second end of the first series inductor and a second end electrically connected to the inverted peaking output, a fourth series inductor having a first end electrically connected to the second end of the second series inductor and a second end electrically connected to the non-inverted peaking output, a third cross capacitor electrically connected between the first end of the third series inductor and the second end of the fourth series inductor, and a fourth cross capacitor electrically connected between the first end of the fourth series inductor and the second end of the third series inductor.

7. The mobile device of claim 1 wherein the front-end system includes a radio frequency module including a module substrate and a semiconductor die attached to the module substrate, the carrier amplifier and the peaking amplifier formed on the semiconductor die.

8. The mobile device of claim 7 wherein the first cross capacitor and the second cross capacitor are formed on the semiconductor die, and the first series inductor and the second series inductor are formed as surface mount components attached to the module substrate.

9. The mobile device of claim 1 wherein the carrier amplifier receives the radio frequency input signal, the Doherty power amplifier further including an input phase shifter configured to receive the radio frequency input signal and to provide a delay radio frequency input signal to the peaking amplifier, the radio frequency input signal and the delayed radio frequency input signal having a phase shift of about ninety degrees.

10. The mobile device of claim 1 wherein the carrier amplifier further includes a first carrier bipolar transistor having a collector electrically connected to the non-inverted carrier output and a second carrier bipolar transistor having a collector electrically connected to the inverted carrier output, the peaking amplifier including a first peaking bipolar transistor having a collector electrically connected to the non-inverted peaking output and a second peaking bipolar transistor having a collector electrically connected to the inverted peaking output.

11. The mobile device of claim 10 wherein the carrier amplifier includes a carrier balun having a secondary winding electrically connected between a base of the first carrier bipolar transistor and a base of the second carrier bipolar transistor, the peaking amplifier further including a peaking balun having a secondary winding electrically connected between a base of the first peaking bipolar transistor and a base of the second peaking bipolar transistor.

12. The mobile device of claim 1 wherein the Doherty power amplifier provides amplification for two or more frequency bands.

13. The mobile device of claim 12 wherein the two or more frequency bands include n255 and n256.

14. A Doherty power amplifier comprising:
an input terminal configured to receive a radio frequency input signal;
a carrier amplifier configured to amplify the radio frequency input signal and having a non-inverted carrier output and an inverted carrier output;
a peaking amplifier configured to amplify the radio frequency input signal and having a non-inverted peaking output and an inverted peaking output; and
an impedance inverter including a first series inductor having a first end electrically connected to the inverted carrier output and a second end electrically connected to the inverted peaking output, a second series inductor having a first end electrically connected to the non-inverted carrier output and a second end electrically connected to the non-inverted peaking output, a first cross capacitor electrically connected between the first end of the first series inductor and the second end of the second series inductor, and a second cross capacitor electrically connected between the first end of the second series inductor and the second end of the first series inductor.

15. The Doherty power amplifier of claim 14 further comprising an output balun having a primary winding electrically connected between the non-inverted peaking output and the inverted peaking output.

16. The Doherty power amplifier of claim 14 wherein the impedance inverter includes two or more stages, a first stage of the two or more stages including the first series inductor, the second series inductor, the first cross capacitor, and the second cross capacitor.

17. The Doherty power amplifier of claim 14 implemented on a radio frequency module including a module substrate and a semiconductor die attached to the module substrate, the carrier amplifier, the peaking amplifier, the first cross capacitor and the second cross capacitor formed on the semiconductor die, and the first series inductor and the second series inductor are formed as surface mount components attached to the module substrate.

18. The Doherty power amplifier of claim 14 wherein the carrier amplifier receives the radio frequency input signal, the Doherty power amplifier further comprising an input phase shifter configured to receive the radio frequency input signal and to provide a delay radio frequency input signal to the peaking amplifier, the radio frequency input signal and the delayed radio frequency input signal having a phase shift of about ninety degrees.

19. The Doherty power amplifier of claim 14 wherein the carrier amplifier includes a first carrier bipolar transistor having a collector electrically connected to the non-inverted carrier output and a second carrier bipolar transistor having a collector electrically connected to the inverted carrier output, the peaking amplifier including a first peaking bipolar transistor having a collector electrically connected to the non-inverted peaking output and a second peaking bipolar transistor having a collector electrically connected to the inverted peaking output.

20. A method of radio frequency signal amplification in a mobile device, the method comprising:
receiving a radio frequency input signal at an input terminal;
amplifying the radio frequency input signal to generate a carrier signal using a carrier amplifier having a non-inverted carrier output and an inverted carrier output;
amplifying the radio frequency input signal to generate a peaking signal using a peaking amplifier having a non-inverted peaking output and an inverted peaking output; and
combining the carrier signal and the peaking signal using an impedance inverter that includes a first series inductor having a first end electrically connected to the inverted carrier output and a second end electrically connected to the inverted peaking output, a second series inductor having a first end electrically connected to the non-inverted carrier output and a second end electrically connected to the non-inverted peaking output, a first cross capacitor electrically connected between the first end of the first series inductor and the second end of the second series inductor, and a second cross capacitor electrically connected between the first end of the second series inductor and the second end of the first series inductor.

21-62. (canceled)
